(19) United States
(12) Patent Application Publication
(10) Pub. No.: US 2024/0321590 A1
(43) Pub. Date: Sep. 26, 2024

(54) SEMICONDUCTOR STRUCTURE, SEMICONDUCTOR DEVICE, AND METHOD

(71) Applicant: Turun yliopisto, Turun yliopisto (FI)

(72) Inventors: Zahra Jahanshah Rad, Turku (FI); Pekka Laukkanen, Turku (FI); Juha-Pekka Lehtiö, Turku (FI); Marko Punkkinen, Turku (FI); Kalevi Kokko, Turku (FI)

(21) Appl. No.: 18/572,938

(22) PCT Filed: Jun. 22, 2022
(86) PCT No.: PCT/FI2022/050459

§ 371 Date: Dec. 21, 2023

(30) Foreign Application Priority Data
Jun. 23, 2021 (FI) 20215741

(51) Int. Cl. H01L 21/324; H01L 29/20

(52) U.S. Cl. CPC H01L 21/3245; H01L 29/20

(57) ABSTRACT

This disclosure relates to a semiconductor structure, a semiconductor device, and a method for forming a semiconductor structure. The semiconductor structure comprises a crystalline III-V semiconductor substrate, the semiconductor substrate comprising a group 13 post-transition metal element and arsenide, and crystalline particles chemically bonded to the semiconductor substrate, the particles comprising the group 13 post-transition metal element and oxygen.

### CROSS-REFERENCE TO RELATED APPLICATIONS

This application is a national phase application of International Patent Application No. PCT/FI2022/050459 (filed 22 Jun. 2022), which claims priority to Finnish Patent Application No. 20215741 (filed 23 Jun. 2021). The entire disclosures of these applications are incorporated herein by reference.

### BACKGROUND

### Technical Field

This disclosure concerns semiconductor technology. In particular, this disclosure concerns III-V semiconductor structures, semiconductor devices, and methods for forming III-V semiconductor structures.

### State of Art

Several III-V semiconductors offer electronic properties superior to silicon. For example, gallium arsenide exhibits an electron mobility and a bandgap higher than those of silicon. Additionally, contrary to silicon, gallium arsenide also has a direct bandgap, facilitating its use in photonics.

However, silicon has certain positive features, which have made it a staple of the semiconductor industry. One of these features is the stable native oxide that spontaneously forms over silicon and can be capitalized on in microfabrication.

In light of this, it may be desirable to develop new solutions related to III-V semiconductor structures.

### SUMMARY

This summary is provided to introduce a selection of concepts in a simplified form that are further described below in the detailed description. This summary is not intended to identify key features or essential features of the claimed subject matter, nor is it intended to be used to limit the scope of the claimed subject matter.

According to a first aspect, a semiconductor structure is provided. The semiconductor structure comprises a crystalline III-V semiconductor substrate, the semiconductor substrate comprising a group 13 post-transition metal element and arsenide, and crystalline particles chemically bonded to the semiconductor substrate, the particles comprising the group 13 post-transition metal element and oxygen.

According to a second aspect, a semiconductor device comprising a semiconductor structure according to the first aspect is provided.

According to a third aspect, a method for forming a semiconductor structure comprising a crystalline III-V semiconductor substrate, the semiconductor substrate comprising a group 13 post-transition metal element and arsenide, and crystalline particles chemically bonded to the semiconductor substrate, the particles comprising the group 13 post-transition metal element and oxygen, is provided. The method comprises subjecting the semiconductor substrate to water of water temperature greater than 40° C. throughout an immersion period with a duration of at least 2 minutes to form the particles.

In an embodiment of the third aspect, the semiconductor structure is a semiconductor structure according to the first aspect.

In an embodiment of the first aspect, the semiconductor structure is obtainable by a method according to the third aspect.

### BRIEF DESCRIPTION OF THE DRAWINGS

The present disclosure will be better understood from the following detailed description read in light of the accompanying drawings, wherein:

FIG. 1 shows a semiconductor structure;

FIG. 2 depicts another semiconductor structure;

FIG. 3 illustrates a semiconductor device;

FIG. 4 shows a method for forming a semiconductor structure;

FIGS. 5A and 5B show a first semiconductor structure and a second semiconductor structure, respectively;

FIGS. 6A and 6B depict the first semiconductor structure and a third semiconductor structure, respectively;

FIGS. 7A and 7B illustrate the third semiconductor structure and a fourth semiconductor structure, respectively;

FIGS. 8A and 8B show a fifth semiconductor structure; and

FIG. 9 depicts a sixth semiconductor structure.

Unless specifically stated to the contrary, any drawing of the aforementioned drawings may be not drawn to scale such that any element in said drawing may be drawn with inaccurate proportions with respect to other elements in said drawing in order to emphasize certain structural aspects of the embodiment of said drawing.

Moreover, corresponding elements in the embodiments of any two drawings of the aforementioned drawings may be disproportionate to each other in said two drawings in order to emphasize certain structural aspects of the embodiments of said two drawings.

### DETAILED DESCRIPTION

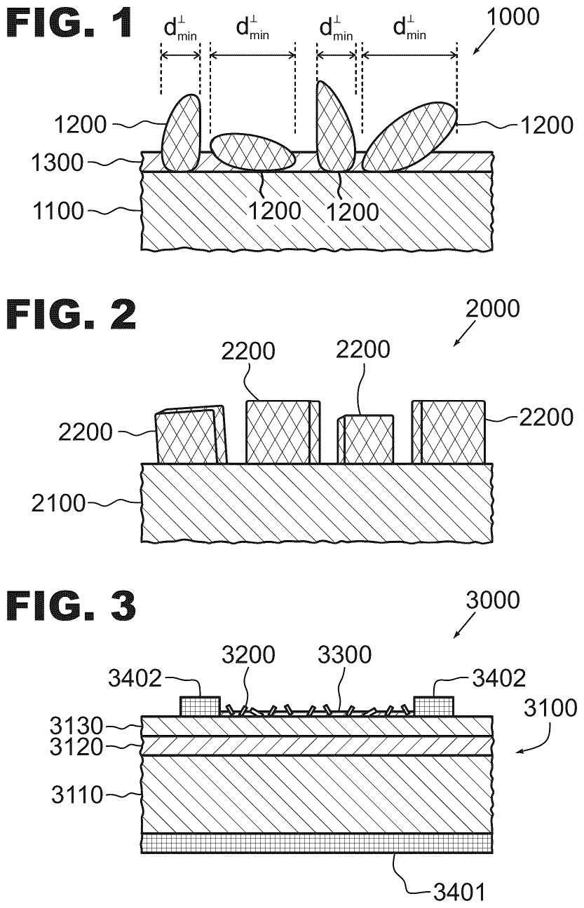

FIG. 1 depicts a semiconductor structure 1000 according to an embodiment.

In this specification, a “semiconductor” may refer to a material, such as gallium arsenide (GaAs), indium arsenide (InAs), or indium gallium arsenide (InGaAs), possessing a conductivity intermediate between the conductivity of conductive materials, such as metals, and the conductivity of insulating materials, such as many plastics and glasses. Generally, a semiconductor may or may not have a crystalline structure.

Herein, “crystalline” structure of a material may refer to constituents, such as atomic nuclei, of said material forming an ordered, three-dimensional crystal lattice.

Further, a “semiconductor structure” may refer to a structure which may comprise all or only part of structural parts, layers, and/or other elements of a complete, operable semiconductor device, such as a transistor, e.g., a power transistor or a phototransistor; a capacitor; a diode, e.g., a photodiode or a power diode; a microprocessor; or a photonics device, e.g., a display, photodetector, or a solar cell. In the case of forming only a part of such component, element, or device, the term “structure” may be considered as a structure “for”, or a building block of, such component, element, or device. In particular, a semiconductor structure may generally comprise non-semiconducting materials, such as conductors and/or insulators, in addition to semiconductor materials.

In the embodiment of FIG. 1, the semiconductor structure 1000 comprises a crystalline III-V semiconductor substrate 1100. The semiconductor substrate 1100 comprises a group 13 post-transition metal element and arsenide (As).

Throughout this disclosure, a “III-V semiconductor substrate” may refer to a solid body made of a III-V semiconductor material and providing a surface onto which material may be deposited. In some embodiments, a III-V semiconductor substrate may comprise a semiconductor wafer formed of a III-V semiconductor material, such as GaAs, InAs, or InGaAs, suitable for manufacturing various semiconductor structures and/or devices, e.g., integrated circuits or photonics devices.

Further, a “group 13 post-transition metal element” may refer to a gallium (Ga), indium (In), or thallium (Tl).

In the embodiment of FIG. 1, the semiconductor structure 1000 comprises crystalline particles 1200 chemically bonded to the semiconductor substrate 1100. The particles 1200 comprise the group 13 post-transition metal element and oxygen (O). Generally, crystalline particles, which comprise a group 13 post-transition metal element and oxygen, being chemically bonded to a crystalline III-V semiconductor substrate comprising the group 13 post-transition metal element and arsenide may decrease the optical reflectance and/or increase the photoluminescence intensity of the semiconductor substrate.

The semiconductor substrate 1100 of the embodiment of FIG. 1 may comprise Ga. In other embodiments, a semiconductor substrate may comprise any group 13 post-transition metal element(s), for example, Ga and/or In.

In particular, the semiconductor substrate 1100 of the embodiment of FIG. 1 may comprise GaAs. In some embodiments, a semiconductor substrate may comprise, consist essentially of, or consist of a III-V compound semiconductor, such as GaAs or InAs. In other embodiments, a semiconductor substrate may comprise a III-V semiconductor alloy, such as InGaAs.

The particles 1200 of the embodiment of FIG. 1 may comprise gallium oxide (Ga₂O₃). In particular, the particles 1200 may comprise cubic defective-spinel-structured γ-Ga₂O₃. In other embodiments, particles may or may not comprise, consist essentially of, or consist of one or more group 13 post-transition metal oxides, such as Ga₂O₃ and/or indium oxide (In₂O₃). In embodiments, wherein particles comprise, consist essentially of, or consist of Ga₂O₃, Ga₂O₃ may be present in the particles any suitable crystalline form(s), for example, as α-Ga₂O₃, and/or β-Ga₂O₃, and/or γ-Ga₂O₃, and/or δ-Ga₂O₃, and/or ε-Ga₂O₃.

In the embodiment of FIG. 1, the particles 1200 have elongated shapes. In other embodiments, particles may have any suitable shapes, for example, elongated or cubical shapes.

The particles 1200 of the embodiment of FIG. 1 are oriented randomly on the semiconductor substrate 1100. Generally, such random orientation of particles may be indicative of a bottom-up fabrication approach used to form such particles. In other embodiments, particles may or may not be oriented randomly on a semiconductor substrate. For example, in some embodiments, a semiconductor substrate may be provided with micro- and/or nanostructures that direct the formation of particles along one or more specific growth directions.

Each of the particles 1200 of the embodiment of FIG. 1 has a projected minimum diameter (dₘᵢₙ^{⊥}) and the particles 1200 have an average projected minimum diameter (dₘᵢₙ^{ave}) of approximately 350 nanometers (nm). Generally, a higher average projected minimum diameter may facilitate decreasing the optical reflectance of a semiconductor substrate. In other embodiments, particles may have any suitable average projected minimum diameter, for example, an average projected minimum diameter greater than or equal to 10 nm, to 20 nm, to 30 nm, to 40 nm, to 50 nm, to 60 nm, to 70 nm, to 80 nm, to 90 nm, to 100 nm, to 110 nm, to 120 nm, to 130 nm, to 140 nm, to 150 nm, to 160 nm, to 170 nm, to 180 nm, to 190 nm, or to 200 nm and/or less than or equal to 1 μm, to 2 μm, to 3 μm, to 4 μm, to 5 μm, to 6 μm, to 7 μm, to 8 μm, to 9 μm, or to 10 μm.

Throughout this specification, an “average projected minimum diameter” of a plurality of particles may refer to a mean of minimum diameters of projections of individual particles of said plurality of particles onto a measurement plane. Herein, a minimum diameter of a projection of a particle onto a measurement plane may be measured along a line extending along said measurement plane via a center point, e.g., a centroid, of said projection. In embodiments, wherein a semiconductor substrate comprises a semiconductor wafer, a measurement plane may extend parallel to a face of said semiconductor wafer.

Although the dₘᵢₙ^{⊥} of the particles 1200 are schematically shown in FIG. 1 as being measured along a single cross-sectional plane of the semiconductor substrate 1100, projected minimum diameters of individual particles of a plurality of particles may or may not generally be measured in such manner. For example, in embodiments, wherein particles are oriented randomly on a semiconductor substrate, projected minimum diameters of said particles may be measured along different cross-sectional planes of said semiconductor substrate.

In the embodiment of FIG. 1, the semiconductor structure 1000 comprises a coating 1300 on the semiconductor substrate 1100. The coating 1300 comprises O, Ga, and As. Generally, a coating comprising O, a group 13 post-transition metal element, and As on a semiconductor substrate comprising the group 13 post-transition metal element and As may facilitate increasing the photoluminescence of the semiconductor substrate. In other embodiments, a semiconductor structure may or may not comprise a coating comprising, consisting essentially of, or consisting of O, a group 13 post-transition metal element, and As on a semiconductor substrate comprising, consisting essentially of, or consisting of the group 13 post-transition metal element and As.

In the embodiment of FIG. 1, the particles 1200 may have an average degree of crystallinity (w^{ave}) of approximately 80 percent by mass (m %). Generally, an average degree of crystallinity of a plurality of particles may be measured using X-ray powder diffraction. In other embodiments, particles may have any suitable average degree of crystallinity, for example, an average degree of crystallinity of at least 40 m %, at least 45 m %, at least 55 m %, at least 60 m %, at least 65 m %, at least 70 m %, at least 75 m %, at least 80 m %, at least 85 m %, at least 90 m %, or at least 95 m %.

FIG. 2 depicts a semiconductor structure 2000 according to an embodiment. The embodiment of FIG. 2 may be in accordance with any of the embodiments disclosed with reference to or in conjunction with FIG. 1. Additionally or alternatively, although not explicitly shown in FIG. 2, the embodiment of FIG. 2 or any part thereof may generally comprise any features and/or elements of the embodiment of FIG. 1 which are omitted from FIG. 2.

In the embodiment of FIG. 2, the semiconductor structure 2000 comprises a crystalline III-V semiconductor substrate 2100 comprising a group 13 post-transition metal element and As as well as crystalline particles 2200 chemically bonded to the semiconductor substrate 2100. The particles 2200 comprise the group 13 post-transition metal element and O.

The semiconductor structure 2000 of the embodiment of FIG. 2 may comprise In. In particular, the semiconductor structure 2000 may comprise InAs.

The particles 2200 of the embodiment of FIG. 2 may comprise indium oxide hydroxide (InOOH). In other embodiments, particles may or may not comprise, consist essentially of, or consist of one or more group 13 post-transition metal oxide hydroxides, such as gallium oxide hydroxide (GaOOH) and/or InOOH.

In the embodiment of FIG. 2, the particles 2200 have cubical shapes. The particles 1200 are oriented randomly on the semiconductor substrate 2100.

It is to be understood that the embodiments of the first aspect described above may be used in combination with each other. Several of the embodiments may be combined together to form a further embodiment.

FIG. 3, depicts a semiconductor device 3000 according to an embodiment. The embodiment of FIG. 3 may be in accordance with any of the embodiments disclosed with reference to or in conjunction with any of FIG. 1 or 2. Additionally or alternatively, although not explicitly shown in FIG. 3, the embodiment of FIG. 3 or any part thereof may generally comprise any features and/or elements of any of the embodiments of FIGS. 1 and 2 which are omitted from FIG. 3.

The semiconductor device 3000 of the embodiment of FIG. 3 is a photodiode and acts as an example of a semiconductor device comprising a semiconductor structure according to the first aspect. In other embodiments, a semiconductor device comprising a semiconductor structure according to the first aspect may or may not be similar or identical to the semiconductor device 3000. In some embodiments, a semiconductor device comprising a semiconductor structure according to the first aspect may be implemented as a transistor, e.g., a MOSFET or a phototransistor; a capacitor, e.g., a supercapacitor; a memristor, a diode, e.g., a photodiode, a light-emitting diode, a laser diode, or a power diode; an integrated circuit, e.g., a microprocessor or a memory chip; or a photonics device, e.g., a display, a photodetector, a radiation detector, or a solar cell.

In the embodiment of FIG. 3, the semiconductor device 3000 comprises a crystalline GaAs semiconductor wafer 3100 acting as a semiconductor substrate. The semiconductor wafer 3100 comprises a donor-doped layer 3110, an intrinsic layer 3120 on the donor-doped layer 3110, and an acceptor-doped layer 3130 on the intrinsic layer 3120.

The semiconductor device 3000 of the embodiment of FIG. 3 further comprises crystalline GaOOH particles 3200 chemically bonded to the acceptor-doped layer 3130; a coating 3300, which may be formed of a mixture of possibly non-stoichiometric Ga and As oxides; as well as a first metal contact 3401 and a second metal contact 3402 connected to the donor-doped layer 3110 and the acceptor-doped layer 3130, respectively.

Above, mainly structural and material features of semiconductor structures and semiconductor devices are discussed. In the following, more emphasis will lie on methods for forming semiconductor structures. What is said above about the ways of implementation, definitions, details, and advantages related to the semiconductor structures and semiconductor devices applies, mutatis mutandis, to the methods discussed below. The same applies vice versa.

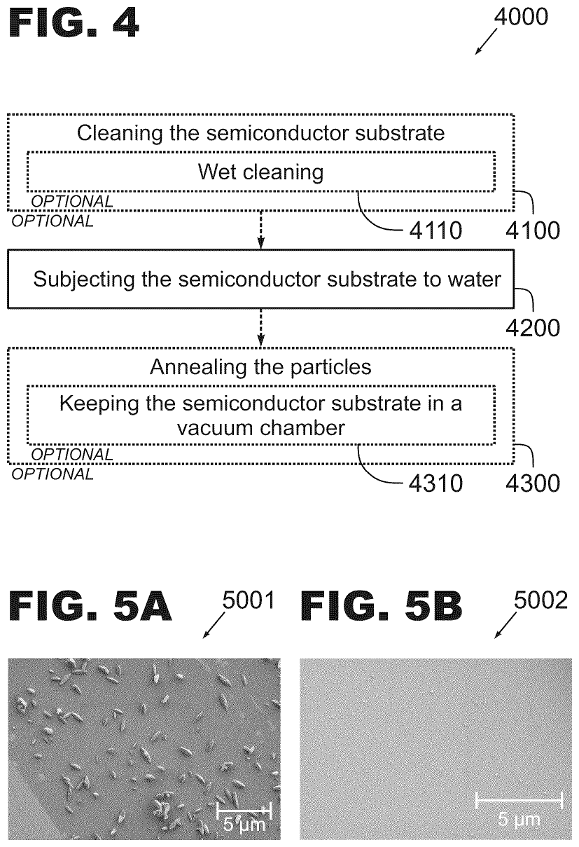

FIG. 4 illustrates a method 4000 for forming a semiconductor structure comprising a crystalline III-V semiconductor substrate, the semiconductor substrate comprising a group 13 post-transition metal element and As, and crystalline particles chemically bonded to the semiconductor substrate, the particles comprising the group 13 post-transition metal element and O. In other embodiments, a method for forming such semiconductor structure may be identical, similar, or different to the method 4000 of the embodiment of FIG. 4.

In the method 4000, the semiconductor structure may be or comprise a semiconductor structure according to the first aspect.

In the embodiment of FIG. 4, the method 4000 comprises subjecting the semiconductor substrate to water 4200 of water temperature, T_{H2O}, greater than 40° C. throughout an immersion period, IP, with a duration, t_{IP}, of at least 5 minutes (min) to form the particles. In other embodiments, a method according to the third aspect may comprise subjecting the semiconductor substrate to water any suitable T_{H2O} greater than 40° C., for example, a T_{H2O} greater than or equal to 42° C., to 45° C., to 47° C., to 50° C., to 52° C., to 55° C., to 57° C., to 60° C., to 62° C., to 65° C., to 70° C., or to 75° C. and/or less than or equal to 100° C., to 98° C., to 95° C., to 90° C., to 85° C. In said other embodiments, IP may have any suitable t_{IP} of at least 5 min, for example, a t_{IP} of greater than or equal to 3 min, to 5 min, to 7 min, to 10 min, to 12 min, to 15 min, to 17 min, to 20 min, to 22 min, to 25 min, to 30 min, to 40 min, to 50 min, or to 60 min and/or less than or equal to 72 h, to 60 h, to 48 h, to 36 h, to 24 h, to 12 h, to 10 h, to 8 h, to 6 h, to 5 h, to 4 h, or to 3 h.

In the embodiment of FIG. 4, the water used for the process of subjecting the semiconductor substrate to water 4200 is ultrapure water. In other embodiments, water of any sufficient purity may be used. For example, in some embodiments, ultrapure water, also known as “high purity water” or “highly purified water”, may be used. In some embodiments, ultrapure water of type 1, 2, 3, 4, or 5 of ASTM standard D1193-06(2018) may be used. In some embodiments, ultrapure water of grade 1, 2, or 3 of ISO standard ISO 3696:1987 may be used.

In this specification, a “process” may refer to a series of one or more steps, leading to an end result. As such, a process may be a single-step or a multi-step process. Additionally, a process may be divisible to a plurality of sub-processes, wherein individual sub-processes of such plurality of sub-processes may or may not share common steps. Herein, a “step” may refer to a measure taken in order to achieve a pre-defined result.

As indicated in FIG. 4 using dotted lines, the method 4000 of the embodiment of FIG. 4 may optionally comprise cleaning the semiconductor substrate 4100 prior to the process of subjecting the semiconductor substrate to water 4200. In other embodiments, a method according to the third aspect may or may not comprise cleaning the semiconductor substrate. For example, in some embodiments, a pre-cleaned semiconductor substrate may be used.

In the embodiment of FIG. 4, the process of cleaning the semiconductor substrate 4100 may comprise a wet cleaning 4110 step, for example, a hydrochloric acid (HCl) wet cleaning step and/or an isopropanol (IPA) wet cleaning step. Generally, utilization of wet cleaning steps increases the scalability of a method for forming a semiconductor structure. In other embodiments, a process of cleaning the semiconductor substrate may comprise any suitable step(s), for example, one or more wet cleaning steps. In embodiments, wherein a process of cleaning the semiconductor substrate comprises one or more wet cleaning steps, said one or more wet cleaning steps may comprise any suitable wet cleaning step(s), for example, a HCl wet cleaning step, and/or an IPA wet cleaning step, and/or an ammonium hydroxide (NH₄OH), and/or a sulfuric acid (H₂SO₄) wet cleaning step. Generally, utilization of different types of cleaning procedures may affect the shapes, and/or sizes, and/or areal number densities of crystalline particles formed on a semiconductor substrate.

As again indicated in FIG. 4 using dotted lines, the method 4000 of the embodiment of FIG. 4 may optionally further comprise annealing the particles 4300 by maintaining temperature (Tₚ) of the particles within an annealing temperature range (ΔT) extending from 200 degrees Celsius (° C.) to 1200° C. throughout an annealing period (AP) with a duration, t_{AP}, of at least 5 minutes. Generally, annealing of particles may increase the amount of group 13 post-transition metal oxides in said particles. In other embodiments, a method according to the third aspect may or may not comprise annealing the particles. In other embodiments, wherein a method according to the third aspect comprises annealing the particles, ΔT may extend, for example, from 220° C. to 1100° C., from 250° C. to 1000° C., from 270° C. to 900° C., from 300° C. to 850° C., from 320° C. to 800° C., from 340° C. to 750° C., from 360° C. to 700° C., from 380° C. to 650° C., or from 400° C. to 600° C. In said embodiments, AP may have any suitable t_{AP}, for example, a t_{AP} of at least 5 min, or at least 5 min, at least 10 min, at least 15 min, at least 20 min, at least 25 min, at least 30 min, at least 35 min, at least 40 min, at least 45 min, at least 50 min, at least 55 min, or at least 60 min.

In the embodiment of FIG. 4, the process of annealing the particles 4300 may optionally comprise keeping the semiconductor substrate in a vacuum chamber 4310 throughout the AP such that total pressure (pₜₒₜ) in the vacuum chamber is maintained below a maximum total pressure (pₜₒₜ^{max}) of 1×10⁻³ millibars (mbar) throughout the AP. In other embodiments, a method according to the third aspect may or may not comprise keeping the semiconductor substrate in a vacuum chamber. In other embodiments, pₜₒₜ may be maintained below any suitable pₜₒₜ^{max}, for example, below a pₜₒₜ^{max} of 1×10⁻³ mbar, or 5×10⁻⁴ mbar, or 1×10⁻⁴ mbar, or tot 5×10⁻⁵ mbar, or 1×10⁻⁵ mbar, or 5×10⁻⁶ mbar, or 2×10⁻⁶ mbar.

In an embodiment, a method according to the third aspect comprises steps implementing processes corresponding to the processes of the method 4000 of the embodiment of FIG. 4. In other embodiments, a method according to the third aspect may comprise steps implementing processes corresponding to the process of subjecting the semiconductor substrate to water 4200 of the method 4000 of the embodiment of FIG. 4.

Generally, steps of a method according to the third aspect implementing processes corresponding to any of the processes of the method 4000 need not be executed in a fixed order. However, any steps implementing a process corresponding to the process of cleaning the semiconductor substrate 4100 of the method 4000 are generally executed prior to steps implementing a process corresponding to the process of subjecting the semiconductor substrate to water 4200, and any steps implementing a process corresponding to the process of subjecting the semiconductor substrate to water 4200 of the method 4000 are generally executed prior to steps implementing a process corresponding to the process of keeping the semiconductor substrate in a vacuum chamber 4310.

In general, a method according to the third aspect may comprise any number of additional processes or steps that are not disclosed herein in connection to the method 4000 of the embodiment of FIG. 4.

It is to be understood that the embodiments of the third aspect described above may be used in combination with each other. Several of the embodiments may be combined together to form a further embodiment.

In the following, a number of examples are detailed.

In a first example, a first semiconductor structure 5001, depicted in the electron micrograph of FIG. 5A, and a second semiconductor structure 5002, depicted in the electron micrograph of FIG. 5B, were formed.

The first semiconductor structure 5001 was formed by providing a crystalline GaAs semiconductor substrate, cleaning the semiconductor substrate using HCl and IPA, and subjecting the semiconductor substrate to water of T_{H2O} of 80° C. throughout an IP with a t_{IP}, of 30 min to form crystalline particles chemically bonded to the semiconductor substrate. The first semiconductor structure 5001 was also subjected to annealing by maintaining the Tₚ of the particles at 350° C. throughout an AP with a t_{AP} of 30 min.

The second semiconductor structure 5002 was formed by providing a semiconductor substrate identical to the semiconductor substrate of the first semiconductor structure 5001, cleaning the semiconductor substrate using HCl and IPA similarly to the semiconductor substrate of the first semiconductor structure 5001, and subjecting the semiconductor substrate to water of T_{H2O} of 50° C. throughout an IP with a t_{IP} of 30 min.

As clearly visible in FIGS. 5A and 5B, reduced particle growth was observed in case of the second semiconductor structure 5002. Such reduced particle growth may be attributed to the lower T_{H2O}.

Energy-dispersive X-ray spectroscopy (EDS) measurements were conducted in order to determine the elemental composition of the particles of the first semiconductor structure 5001. Based on the measurements, the particles consisted essentially of Ga and O.

Further, in order to determine the effect of the annealing process undergone by the particles of the first semiconductor structure 5001, a further semiconductor structure was formed using a method similar to the method used to form the first semiconductor structure 5001. However, contrary to the first semiconductor structure 5001, the further semiconductor structure was not annealed following the procedure of subjecting the semiconductor substrate to water.

X-ray diffraction (XRD) measurements were conducted in order to determine the crystalline structures of the particles of the first semiconductor structure 5001 and those formed on the semiconductor substrate of the further semiconductor structure. According to the results, the particles of the first semiconductor structure 5001 comprised defective-spinel-structured γ-Ga₂O₃, whereas the particles on the semiconductor substrate of the further semiconductor structure comprised GaOOH.

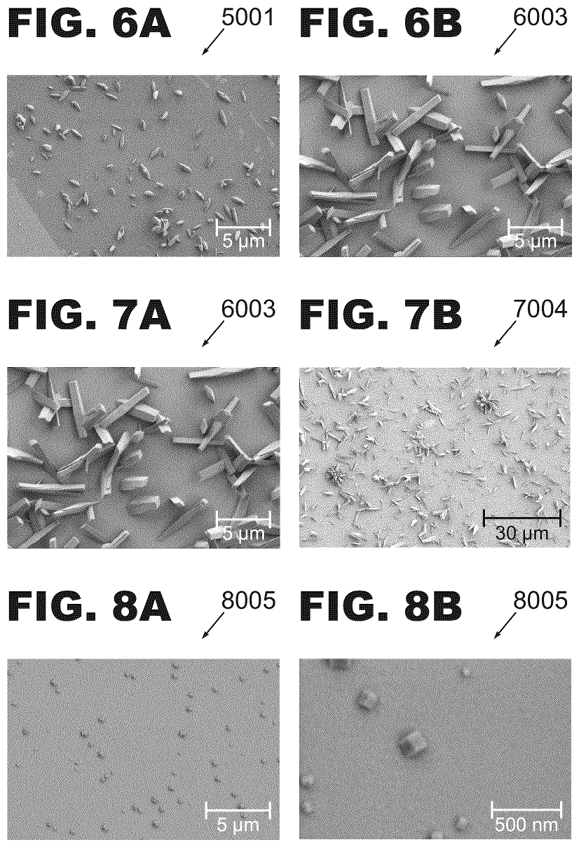

In a second example, a third semiconductor structure 6003, depicted in the electron micrograph of FIG. 6B, was formed by providing a crystalline GaAs semiconductor substrate, cleaning the semiconductor substrate using HCl and IPA, and subjecting the semiconductor substrate to water of T_{H2O} of 80° C. throughout an IP with a t_{IP} of 150 min to form crystalline particles chemically bonded to the semiconductor substrate.

The third semiconductor structure 6003 was formed using a method similar to the one used to from the first semiconductor structure 5001 of the first example. However, the third semiconductor structure 6003 was subjected to ultrapure water for a longer IP and not subjected to annealing. The first semiconductor structure 5001 is illustrated in FIG. 6A.

As clearly visible in FIGS. 6A and 6B, increased particle sizes were observed in case of the third semiconductor structure 6003. Such increased particle sizes may be attributed to the longer IP.

Further, photoluminescence and optical reflectance measurements were used to assess the effect of the particles of the third semiconductor structure 6003 on the optical properties of the crystalline GaAs semiconductor substrate of the third semiconductor structure 6003. During the measurements, crystalline GaAs semiconductor substrates coated with native oxide layers were used as reference samples. Based on the results, the particles increased the intensity of measured photoluminescence approximately eight-fold at a wavelength of approximately 850 nm and reduced the reflectance by nearly half, for example, from approximately 37% to approximately 24% at a wavelength of 550 nm, compared to the measured photoluminescence and the reflectance of the reference samples, respectively.

In a third example, a fourth semiconductor structure 7004, depicted in the electron micrograph of FIG. 7B, was formed by providing a crystalline GaAs semiconductor substrate, cleaning the semiconductor substrate using HCl and IPA, and subjecting the semiconductor substrate to water of T_{H2O} of 100° C. throughout an IP with a t_{IP} of 120 min to form crystalline particles chemically bonded to the semiconductor substrate.

The fourth semiconductor structure 7004 was formed using a method similar to the one used to from the third semiconductor structure 6003 of the second example. However, the fourth semiconductor structure 7004 was formed with a higher T_{H2O}. The third semiconductor structure 6003 is illustrated in FIG. 7A.

In addition to the particles, the fourth semiconductor structure 7004 comprised a rough, amorphous coating covering the semiconductor substrate. Additionally, contrary to the third semiconductor structure 6003, the particles were unevenly dispersed throughout the surface of the semiconductor substrate such that considerable portions of the surface of the semiconductor substrate lacked any particles.

In a fourth example, a fifth semiconductor structure 8005, depicted in the electron micrographs of FIGS. 8A and 8B, was formed by providing a crystalline InAs semiconductor substrate, cleaning the semiconductor substrate using HCl and IPA, and subjecting the semiconductor substrate to water of T_{H2O} of 70° C. throughout an IP with a t_{IP} of 120 min to form crystalline particles chemically bonded to the semiconductor substrate, the particles having cubical shapes.

EDS measurements were conducted in order to determine the elemental composition of the particles of the fifth semiconductor structure 8005. Based on the measurements, the particles comprised both In and O.

Further, in order to determine the effect of changes in T_{H2O} on the particle growth, two further semiconductor structure samples were formed, one of which was formed using a T_{H2O} of 60° C. and the other of which was formed using a T_{H2O} of 80° C. Considerably reduced particle growth was observed in case of both of the two further semiconductor structure samples.

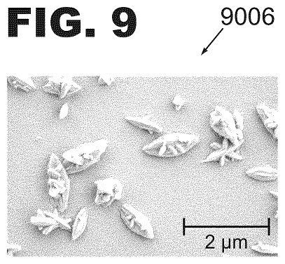

In a fifth example, a sixth semiconductor structure 9006, depicted in the electron micrograph of FIG. 9, was formed by providing a crystalline GaAs semiconductor substrate, cleaning the semiconductor substrate using HCl and IPA, subjecting the semiconductor substrate to water of T_{H2O} of 80° C. throughout an IP with a t_{IP} of 30 min to form crystalline particles chemically bonded to the semiconductor substrate, annealing the particles by maintaining the Tₚ of the particles at 400° C. throughout an AP with a t_{AP} of 40 min, and keeping the semiconductor substrate in a vacuum chamber throughout the AP such that pₜₒₜ in the vacuum chamber was maintained below a pₜₒₜ^{max} of 1×10⁻³ mbar throughout the AP. The resulting polycrystalline particles were observed to have spiky and jagged shapes.

In a sixth example, another semiconductor structure was formed by providing a semiconductor substrate comprising an n-type GaAs emitter layer, a gallium indium phosphide (GaInP) confinement layer over the emitter layer, a first barrier layer formed of GaAs over the confinement layer, a gallium indium arsenide (GaInAs) quantum well layer over the first barrier layer, and a second barrier layer formed of GaAs over the quantum well layer and by subjecting the semiconductor substrate to water of T_{H2O} of 80° C. throughout an IP with a t_{IP} of 30 min to form crystalline particles chemically bonded to the semiconductor substrate. Following the formation of the crystalline particles, the semiconductor substrate of the sixth example exhibited increased photoluminescence and reduced visible light reflectance compared to a similar reference sample without such particles. The increase of photoluminescence intensity and reduction in reflectance were observed even two weeks after the formation of the particles.

In a seventh example, yet another semiconductor structure was formed by mechanically abrading a GaAs semiconductor substrate prior to subjecting the semiconductor substrate to water of T_{H2O} of 80° C. throughout an IP with a t_{IP} of 150 min to form crystalline particles chemically bonded to the semiconductor substrate. Due to the process of mechanically abrading a GaAs semiconductor substrate, crystalline particles were formed with a higher surface density onto unabraded portions of the semiconductor substrate and with a considerably lower surface density onto abraded portions of the semiconductor substrate. In other embodiments, a method for forming a semiconductor structure comprising a crystalline III-V semiconductor substrate, the semiconductor substrate comprising a group 13 post-transition metal element and arsenide, and crystalline particles chemically bonded to the semiconductor substrate, the particles comprising the group 13 post-transition metal element and oxygen, may or may not comprise mechanically abrading a semiconductor substrate prior to a process of subjecting the semiconductor substrate to water.

In an eight example, still another semiconductor structure was formed by subjecting a GaAs semiconductor substrate to argon (Ar) ion sputtering prior to subjecting the semiconductor substrate to water of T_{H2O} of 80° C. throughout an IP with a t_{IP} of 150 min to form crystalline particles chemically bonded to the semiconductor substrate. The ion sputtering can be carried out, for example, in room temperature. It has also been found that the nanocrystal density may be the same also if higher temperatures, such as 350° C., are used. Due to the process of subjecting the semiconductor substrate to ion sputtering, crystalline particles were formed with a lower surface density onto the semiconductor substrate. In other embodiments, a method for forming a semiconductor structure comprising a crystalline III-V semiconductor substrate, the semiconductor substrate comprising a group 13 post-transition metal element and arsenide, and crystalline particles chemically bonded to the semiconductor substrate, the particles comprising the group 13 post-transition metal element and oxygen, may or may not comprise subjecting the semiconductor substrate to ion sputtering, such as Ar ion sputtering, prior to a process of subjecting the semiconductor substrate to water.

### FURTHER EXAMPLES

In the following, further examples and additional features thereof are presented by which various advantageous results may be achieved.

### Further Example 1

It has been found that it may be possible to reduce the size of nano crystals and increase their density by the following process. GaAs is first chemically cleaned by HCl+IPA for 3 min, then HW treatment is applied at 80° C. for 150 min followed by abrading nanocrystals. A second round of chemical cleaning and HW is applied on the same sample after abrading.

The abrading to remove nanocrystals may be an important factor for formation of smaller particles. Breaking existing nanocrystals during the mechanical removal may form new nuclei for the growth of smaller nanocrystals (nano wires) during the second HW treatment. It may be possible to omit the step of chemical cleaning.

### Further Example 2

The amount of As in HW may affect the growth of nanocrystals. Higher As concentration may result in less growth. Advantageous results have been achieved, for example, by having the As concentration range in HW in the range of 0.012-0.026 mg/ml and carrying out the HW treatment at 80° C. for 150 min in the water with high As concentration.

### Further Example 3

It has been found possible to grow smaller nanostructures on the substrate of a sample with the following procedure starting by chemical cleaning->HW at 80° C. for 150 min->abrading nanocrystals->storing nanocrystals in IPA. The process then continues by immersing the sample into IPA with nanocrystals harvested from another sample. Then the second sample was HW treated. Smaller nanocrystals may then grow, as seen in SEM images of the samples, on the substrate.

Optionally, in the process explained above, the GaAs substrate may be cleaned prior to immersion into nanocrystals+IPA to facilitate formation of smaller nanocrystals on the GaAs substrate.

### Further Example 4

Using a chemical pre-treatment of H2O2:ammonia (20:1) for 20 seconds at room temperature prior to HW treatment at 80° C. for 150 min may result in the formation of arsenic oxide nanocrystals on the substrate.

### Further Example 5

After UHV heating of GaOOH nanocrystals and changing their phase to Ga2O3, nanocrystals morphology and density may be the same as before UHV heating.

This has been confirmed in a SEM image from GaAs 45 after UHV heating at 450° C. for 4 hours. This sample was a GaAs substrate which had been exposed to IPA+HCl cleaning and then it was HW treated for 150 min at 80° C. prior to UHV heating.

It is obvious to a person skilled in the art that with the advancement of technology, the basic idea of the invention may be implemented in various ways. The invention and its embodiments are thus not limited to the examples described above, instead they may vary within the scope of the claims.

It will be understood that any benefits and advantages described above may relate to one embodiment or may relate to several embodiments. The embodiments are not limited to those that solve any or all of the stated problems or those that have any or all of the stated benefits and advantages.

The term “comprising” is used in this specification to mean including the feature(s) or act(s) followed thereafter, without excluding the presence of one or more additional features or acts. It will further be understood that reference to ‘an’ item refers to one or more of those items.

REFERENCE SIGNS AND ABBREVIATIONS

| dₘᵢₙ^{⊥} projected minimum diameter | |
|---|---|
| dₘᵢₙ^{ave} average projected minimum diameter | |
| w^{ave} average degree of crystallinity | |
| IP immersion period | |
| t_{IP} duration of the immersion period | |
| T_{H2O} water temperature | |
| Tₚ temperature of the particles | |
| ΔT annealing temperature range | |
| AP annealing period | |
| t_{AP} duration of the annealing period | |
| Pₜₒₜ total pressure | |
| pₜₒₜ^{max} maximum total pressure | |
| 1000 semiconductor | 3200 particle |
| structure | 3300 coating |
| 1100 semiconductor | 3401 first metal contact |
| substrate | 3402 second metal contact |
| 1200 particle | 4000 method |
| 1300 coating | 4100 cleaning the |
| 2000 semiconductor | semiconductor substrate |
| structure | 4110 wet cleaning |
| 2100 semiconductor | 4200 subjecting the |
| substrate | semiconductor substrate |
| 2200 particle | to water |
| 3000 semiconductor device | 4300 annealing the |
| 3100 semiconductor wafer | particles |
| 3110 donor-doped layer | 4310 keeping the |
| 3120 intrinsic layer | semiconductor substrate |
| 3130 acceptor-doped layer | in a vacuum chamber |
| 5001 first semiconductor | 7004 fourth semiconductor |
| structure | structure |
| 5002 second semiconductor | 8005 fifth semiconductor |
| structure | structure |
| 6003 third semiconductor | 9006 sixth semiconductor |
| structure | structure |

1. A semiconductor structure, comprising:
a crystalline III-V semiconductor substrate, the semiconductor substrate comprising a group 13 post-transition metal element and arsenide, As; and
crystalline particles chemically bonded to the semiconductor substrate, the particles comprising the group 13 post-transition metal element and oxygen, O.

2. The semiconductor structure according to claim 1, wherein the particles comprise one or more group 13 post-transition metal oxides.

3. The semiconductor structure according to claim 1, wherein the particles comprise one or more group 13 post-transition metal oxide hydroxides.

4. The semiconductor structure according to claim 1, wherein the semiconductor substrate comprises one or more of gallium, Ga, or indium, In.

5. The semiconductor structure according to claim 1, wherein the semiconductor substrate comprises one or more of a III-V compound semiconductor or a III-V semiconductor alloy.

6. The semiconductor structure according to claim 1, wherein the particles have elongated shapes, cubical shapes, or spiky and jagged shapes.

7. The semiconductor structure according to claim 1, wherein the particles are oriented randomly on the semiconductor substrate.

8. The semiconductor structure according to claim 1, wherein the particles have an average projected minimum diameter, dₘᵢₙ^{ave} that is one or more of:
(a) greater than or equal to 10 nm, to 20 nm, to 30 nm, to 40 nm, to 50 nm, to 60 nm, to 70 nm, to 80 nm, to 90 nm, to 100 nm, to 110 nm, to 120 nm, to 130 nm, to 140 nm, to 150 nm, to 160 nm, to 170 nm, to 180 nm, to 190 nm, or to 200 nm, or
less than or equal to 1 μm, to 2 μm, to 3 μm, to 4 μm, to 5 μm, to 6 μm, to 7 μm, to 8 μm, to 9 μm, or to 10 μm.

9. The semiconductor structure according to claim 1, wherein the particles have an average degree of crystallinity, w^{ave}, of at least 40 m %, at least 45 m %, at least 55 m %, at least 60 m %, at least 65 m %, at least 70 m %, at least 75 m %, at least 80 m %, at least 85 m %, at least 90 m %, or at least 95 m %.

10. the semiconductor structure according to claim 1, wherein the semiconductor structure comprises a coating on the semiconductor substrate, the coating comprising oxygen, O; the group 13 post-transition metal element, and arsenide, As.

11. the semiconductor structure according to claim 1, wherein the semiconductor structure is obtainable by a method according to claim 13.

12. The semiconductor device, comprising a semiconductor structure according to claim 1.

13. A method for forming a semiconductor structure comprising a crystalline III V semiconductor substrate, the semiconductor substrate comprising a group 13 post-transition metal element and arsenide, As, and crystalline particles chemically bonded to the semiconductor substrate, the particles comprising the group 13 post-transition metal element and oxygen, O, the method comprising:
subjecting the semiconductor substrate to water of water temperature, T_{H2O}, greater than 40° C. throughout an immersion period, IP, with a duration, t_{IP}, of at least 2 min to form the particles.

14. The method according to claim 13, wherein the method comprises cleaning the semiconductor substrate prior to subjecting the semiconductor substrate to water.

15. The method according to claim 14, wherein cleaning the semiconductor substrate comprises a wet cleaning step.

16. The method according to claim 13, wherein the method comprises annealing the particles by maintaining a temperature, Tₚ, of the particles within an annealing temperature range, ΔT, extending from 200° C. to 1200° C. throughout an annealing period, AP, with a duration, t_{AP}, of at least 5 min.

17. The method according to claim 16, wherein the annealing temperature range, ΔT, extends from 220° C. to 1100° C., from 250° C. to 1000° C., from 270° C. to 900° C., from 300° C. to 850° C., from 320° C. to 800° C., from 340° C. to 750° C., from 360° C. to 700° C., from 380° C. to 650° C., or from 400° C. to 600° C.

18. The method according to claim 16, wherein the duration, t_{AP}, of the annealing period, AP, is at least 5 min, at least 10 min, at least 15 min, at least 20 min, at least 25 min, at least 30 min, at least 35 min, at least 40 min, at least 45 min, at least 50 min, at least 55 min, or at least 60 min.

19. The method according to claim 16, wherein annealing the particles comprises keeping the semiconductor substrate in a vacuum chamber throughout the annealing period, AP, such that total pressure, pₜₒₜ, in the vacuum chamber is maintained below a maximum total pressure, pₜₒₜ^{max}, of 1×10⁻³ mbar throughout the annealing period, AP.

20. The method according to claim 19, wherein the maximum total pressure, pₜₒₜ^{max}, is 5×10⁻⁴ mbar, or 1×10⁻⁴ mbar, or 5×10⁻⁵ mbar, or 1×10⁻⁵ mbar, or 5×10⁻⁶ mbar, or 2×10⁻⁶ mbar.

21. The method according to claim 13, wherein the water temperature, T_{H2O}, is one or more of: (a) greater than or equal to 42° C., to 45° C., to 47° C., to 50° C., to 52° C., to 55° C., to 57° C., to 60° C., to 62° C., to 65° C., to 70° C., or to 75° C. or (b) less than or equal to 100° C., to 98° C., to 95° C., to 90° C., to 85° C.

22. The method according to claim 13, wherein the duration, t_{IP}, of the immersion period, IP, is greater than or equal to 3 min, to 5 min, to 7 min, to 10 min, to 12 min, to 15 min, to 17 min, to 20 min, to 22 min, to 25 min, to 30 min, to 40 min, to 50 min, or to 60 min and/or less than or equal to 72 h, to 60 h, to 48 h, to 36 h, to 24 h, to 12 h, to 10 h, to 8 h, to 6 h, to 5 h, to 4 h, or to 3 h.

23. The method according to claim 13, wherein the method comprises mechanically abrading the semiconductor substrate prior to subjecting the semiconductor substrate to water.

24. The method according to claim 13, wherein the method comprises subjecting the semiconductor substrate to ion sputtering prior to subjecting the semiconductor substrate to water.

25. The method according to claim 13, wherein the semiconductor structure is a semiconductor structure according to claim 1.
